(19) United States
(12) Patent Application Publication
(10) Pub. No.: US 2024/0404786 A1
(43) Pub. Date: Dec. 5, 2024

(54) METHOD TO INVESTIGATE A SEMICONDUCTOR SAMPLE LAYER BY LAYER AND INVESTIGATION DEVICE TO PERFORM SUCH METHOD

(71) Applicant: Carl Zeiss SMT GmbH, Oberkochen (DE)

(72) Inventors: Ivo IHRKE, Scheuerfeld (DE); Martin ROSS-MESSEMER, Essingen (DE); Jens Timo NEUMANN, Aalen (DE); Arian KRIESCH, Aalen (DE)

(21) Appl. No.: 18/795,411

(22) Filed: Aug. 6, 2024

Related U.S. Application Data
(63) Continuation of application No. PCT/EP2023/051768, filed on Jan. 25, 2023.

(30) Foreign Application Priority Data
Feb. 10, 2022 (DE) 10 2022 201 394.8

(51) Int. Cl. H01J 37/305; G01N 1/32; G01N 23/2252; H01J 37/28

(52) U.S. Cl. CPC H01J 37/3056; G01N 1/32; G01N 23/2252; H01J 37/28; G01N 2223/418; H01J 2237/2442; H01J 2237/31745; H01J 2237/31749

(57) ABSTRACT

A method includes preparing an initial layer of a semiconductor sample., and aligning a surface area of a region of interest volume of the prepared layer with an object field of an SEM. An electron energy of an electron beam of the SEM is adjusted. The region of interest volume is probed with the SEM within the object field. X-rays emanating from the aligned region of interest volume are detected. A detection signal is post-processed to deconvolute the detection signal into structured data attributed to the sample structure within the region of interest volume. A next layer to be investigated is prepared by FIB etching and the steps “preparing” to “post-processing” are repeated until the layer by layer investigation of a superimposed volume of interest of the sample is completed.

### CROSS-REFERENCE TO RELATED APPLICATIONS

The present application is a continuation of, and claims benefit under 35 USC 120 to, international application No. PCT/EP2023/051768, filed Jan. 25, 2023, which claims benefit under 35 USC 119 of German Application No. 10 2022 201 394.8, filed Feb. 10, 2022. The entire disclosure of each of these applications is incorporated by reference herein.

### FIELD

The disclosure relates to methods of investigating a semiconductor sample layer by layer using focused ion beam etching and X-ray detection, as well as related devices.

### BACKGROUND

An investigation device to investigate a semiconductor sample using a focused ion beam/scanning electron beam (FIB/SEM) crossbeam scheme is disclosed in U.S. Pat. No. 8,969,835 B2. An investigation method using X-ray spectrometry in an SEM is known.
M. Cantoni, L. Holzer: Advances in 3D focused ion beam tomography MRS Bulletin volume 39, pages 354-360 (2014) discloses details of focused ion beam tomography.
L. Holder, M. Cantoni: Review of FIB tomography. In I. Utke, S. Moshkalev, & P. Russell (Eds.), Oxford series on nanomanufacturing, Nanofabrication using focused ion and electron beams, Principles and applications (pp. 410-435), 2012 discloses details of focused ion beam (FIB) tomography.
P. Burdet: Three Dimensional Microanalysis by Energy Dispersive Spectrometry: Improved Data Processing. Phd thesis, École Polytechnique Fédérale de Lausanne, 2012 discloses a combined microscopy technique, i.e. energy dispersive spectrometry (EDS) extended to 3D microanalysis using an electron microscope equipped with a focused ion beam.
P. Burdet, C. Hébert, M. Cantoni: Enhanced Quantification for 3D Energy Dispersive Spectrometry: Going Beyond the Limitation of Large Volume of X-Ray Emission. Microsc. Microanal. 20, 1544-1555, 2014 discloses a method developed to quantify three-dimensional energy dispersive spectrometry data with a voxel size smaller than a volume from which x-rays are emitted.
P-Burdet, S. A. Croxall, P. A. Midgley: Enhanced quantification for 3D SEM-EDS: Using the full set of available X-ray lies, Ultramicroscopy 148, 158-167, 2015 discloses the use of all available x-ray lines generated by a beam during a method to quantify energy dispersive spectra recorded in 3D with a scanning electron microscope.
L. Struder, A. Niculae, P. Holl, H. Soltau: Development of the Silicon Drift Detector for Electron Microscopy Applications. Microscopy Today, Volume 28, Issue 5, September 2020 gives details regarding the development of a silicon drift detector.
U.S. Pat. No. 6,924,484 B1 discloses a void characterization in metal interconnect structures using x-ray emission analyses.
WO 2019/071352 A1 discloses a method for cross-section sample preparation.
EP 2 557 584 A1 discloses a charged-particle microscopy imaging method.
U.S. Pat. No. 11,282,670 B1 discloses a slice depth reconstruction of charged particle images using model simulation for improved generation of 3D sample images.
US 2022/0102121 A1 discloses a depth reconstruction for 3D images of samples in a charged particle system.

### SUMMARY

The disclosure seeks to improve an investigation method mentioned to improve the volumetric spatial resolution within a volume of interest and, for example, to improve elemental information from the region of interest volume.

In an aspect, the disclosure provides a method of investigating a semiconductor sample having a sample surface layer by layer using focused ion beam (FIB) etching and X-ray detection, the sample having structures of different elemental composition, the method comprising: preparing a layer to be investigated of the semiconductor sample by etching an initial sample surface with a FIB; aligning a surface area of a region of interest volume of the prepared layer of the sample with an object field of a scanning electron microscope (SEM); adjusting an electron energy of an electron beam of the SEM; probing the region of interest volume with the scanning electron beam within the object field; detecting X-rays emanating from the aligned region of interest volume; post-processing of a detection signal obtained during the detection step to spatially deconvolute the detection signal into structure data attributed to the sample structure within the region of interest volume; and repeating “preparing” to “post-processing” until layer by layer investigation of a superimposed volume of interest of the sample is completed.

The number of layers which are prepared during the method can be in the region between 2 and 100. In addition to the detection of X-rays from inelastic electron/material interaction, also Auger electrons (AE) may be detected. The post-processing results in an increased volumetric spatial resolution within the volume of interest. Such volumetric spatial resolution may be better than 25 nanometers (nm), better than 20 nm, better than 15 nm and may be better than 10 nm. Practically, such volumetric spatial resolution is above 1 nm. The definition of such volumetric spatial resolution is done with the help of an edge resolution criterion to distinguish between adjacent structures. Examples of edge resolution criteria are known.

Post-processing may include an optimization algorithm. With the investigation method, an investigation of chip structures, such as semiconductor memory structures, flash memory structures, NAND structures, 3D-NAND structures and vertical 3D-NAND structures, is possible.

X-ray detection can be performed in a wavelength dependent manner. This can further improve the versatility of the investigation method. In addition to a spectral X-ray detection detecting inelastic scattered X-rays (EDX), also Auger electrons (AE) may be detected. Such EDX and/or AE detection results in elemental information from the region of interest volume.

Typical detected X-ray energies can range between 50 electron Volts (eV) and 3 keV. Lines to be detected can include K, L, M and N lines of the respective elements within the sample to be investigated. In that respect, it is noted that 277 eV attributes to carbon, 392 eV attributes to nitrogen, 452 eV attributes to titanium, 525 eV attributes to oxygen, 1486 eV attributes to aluminum, 1740 eV attributes to silicon, 1775 eV attributes to tungsten. In an example, electron energies below 1000 eV are used. Such electron energies can result in better post-processing deconvolution effects. A further improvement of the volumetric spatial resolution is possible by exploiting a wavelength-dependent X-ray detection and/or lower electron energies.

The post-processing step can take into account that a free interaction path length of the probe electrons depends on the material density and therefore depends on the elemental composition.

Further, an occurrence and/or amount of dopants can be investigated with the method.

It is generally desirable to increase 3D resolution in analytic tomographic FIB-SEM imaging, i.e. the spatially three-dimensional acquisition of spectral X-ray data for material imaging within a sample volume (EDS/EDX) in bulk material. The method involves the effect of X-ray emission due to excitation of inner atomic shell electrons by the kinetic energy of the electrons in the electron beam of the microscope (and their subsequent relaxation). The excitation can occur in a sample volume known as the interaction volume or as the region of interest volume.

Conventionally, a resolution limiting aspect of the technique is a size of the interaction volume of the electron beam with the sample, i.e. the size of the sample volume where the primary electrons have sufficient energy to excite X-ray emission.

The size of the interaction volume generally increases with increasing beam energy (acceleration voltage), which would imply a low value for high resolution. On the other hand, the electrons desirably have a sufficient kinetic energy to excite the inner atomic shell electrons, optionally for a wide range of possible elements that may be present in a sample. This can put the practical lowest energy range at ≈1 kiloectron Volt (keV). The de Broglie wavelength is ≈38 picometers (pm) in this case. However, depending on the element and how exactly the extent of the interaction volume is measured, the size of the interaction volume may be in the order of ≈20 nm.

High-resolution EDX scanning may use low electron beam energies in order to minimize the size of the electron interaction volumes in the sample. An X-ray photon generation efficiency is very low at the low beam energies employed in the example. This conventionally results in a trade-off between resolution and acquisition times.

Using the post-processing within the investigation method can result in algorithmic super-resolution techniques enhancing the analytic EDX resolution. A spatial mixing behavior introduced by the interaction volume may be mathematically modeled by computational methods within the post-processing step. This may utilize a reasonably realistic mathematical model of the measurement/interaction process.

Approximations may be used during post-processing to derive a feasible mathematical model for the spatial inversion/deconvolution. This may include a recovery of high-resolution material maps from a 3D stack of spatio-spectrally resolved EDX measurements, i.e. from a spatial and as well from a spectral resolution. Such recovery may include a formulation on elemental emission lines which involves a process of the acquired EDX spectra to extract the contribution of different elemental lines to the observed spectra. Information from different modalities may be used to support the recovery task.

A general measurement setting may be a spatio-spectrally resolved 3D EDX scan that may have an arbitrary scan geometry. The measurement geometry may be a cross-beam configuration (ion beam/electron beam) or a tilted FIB acquisition, i.e. a tilt angle ranging between 0° and 90° between the ion (FIB) and the electron (SEM) beam. A result of the investigation method may be a rectified, sharpened volume of material maps for the different elements that are present in the sample.

Post-processing refinements disclosed herein can enable a further improvement in volumetric spatial resolution and/or in elemental information within the region of interest volume.

Post-processing can include geometry input or other a priori condition input from further measurements. Such geometry input or other a prior condition input can be achieved with further independent measurements. SEM imaging may provide such further geometry input and/or a priory condition input. A known geometry can be used to improve a resolution capability of the post-processing step. Other material dependent conditions obtained from a material library may contribute to the a priori condition input of the post-processing step.

During the investigation the following takes place: defining a Point Spread Function that, for each value of n, has a kernel value Kₙ representing the behavior of the probing beam in a bulk of the sample for a given beam parameter value; defining a spatial variable V that represents a physical property of the sample as a function of position in its bulk; defining an imaging quantity that, for each value of n, has a value Qₙ that is a multi-dimensional convolution of Kₙ and V, such that Qₙ=Kₙ*V; or each value of n, computationally determining a minimum divergence

$$min D ( {M}_{n} ‖ {K}_{n} * V )$$

between Mₙ and Qₙ, which is solved for V while applying constraints on the values Kₙ. Such post-processing is a variant to deconvolute measured data and to generate a sample image with a relatively high resolution. Reference is made to EP 2 557 584 A1. Such a minimum divergence can be a Least Squares Distance, Csiszar-Morimoto F-divergences, Bregman Divergences, Alpha-Beta-Divergences, the Bhattacharyya Distance, the Cramér-Rao Bound and/or derivatives of these.

The constraints on the values Kₙ can be derived using at least one method selected from the group comprising: computational simulation of at least a set of values Kₙ; empirical determination of at least a set of values Kₙ; modelling of the Point Spread Function as a parametrized function with a limited number of modeling parameters, on the basis of which at least a set of values Kₙ can be estimated; logical solution space limitation, whereby theoretically possible values Kₙ that are judged to be physically meaningless are discarded; and interference of a second set of values Kₙ by applying extrapolation and/or interpolation to a first set of values Kₙ. Such value constraints can be desirable. Such computational simulation can be performed with the aid of a Monte-Carlo simulation and/or a Finite Element Analysis.

The beam parameter of the focused ion beam and/or the electron beam may be selected from the following parameters: beam energy, beam convergence angle and/or beam focused depth.

During the investigation method, simulated radiation emitted by the sample during the respective measurement may be detected. Such stimulated radiation may be secondary electrons, backscattered electrons and/or x-ray radiation. An intensity and/or a current measurement may take place.

A physical property of the spatial variable may be an agent concentration, an atomic density and/or a secondary emission coefficient.

A material removal method during the respective preparation step may be mechanically slicing with a cutting device, may be ion milling with an ion beam, may be ablation with an electromagnetic beam, may be beam-induced etching, may be chemical etching and/or may be reactive etching.

During the investigation method, a physical slicing step may be combined with a computational slicing step. These physical/computational slicing steps may alternately be repeated.

The disclosure seeks to provide an investigation device capable to perform the investigation method.

In an aspect, the disclosure provides an investigation device to perform a method disclosed herein, wherein the device comprises: a FIB source; an SEM; an X-ray detection device detecting X-rays emanating from the sample, the X-rays being produced by the probe electrons of the SEM; and a computer to perform the post-processing of a detection signal obtained by the X-ray detection device. Optionally, the X-ray detection device includes an X-ray spectrometer. Features of such investigation devices correspond to those mentioned above with respect to the investigation method.

The device can be arranged such that the SEM probes the sample under 90° measured from an initial bulk sample surface plane. The device can be arranged such that the X-ray detection device detects the X-rays under 90° measured from an initial bulk sample surface plane. Such arrangements have proven to decrease or avoid an unwanted contamination of the region of interest volume with ions and/or debris caused by the FIB etching preparation steps.

An angle between the etching plane and the initial bulk sample surface plane may be in the region between 20° and 40° and may be around 35°.

Exemplified embodiments of the disclosure are hereinafter described with reference to the accompanying drawings.

### BRIEF DESCRIPTION OF THE DRAWINGS

FIG. 1 schematically an investigation device to perform an investigation method to investigate a semiconductor sample layer by layer including a FIB source, an SEM and an X-ray detection device;

FIG. 2 a sample investigation geometry indicating an orientation of an FIB etching plane defining subsequent sample layers to be prepared via FIB etching, an initial bulk sample surface plane of the semiconductor sample to be investigated and an SEM probe direction which coincides with an X-ray detection direction;

FIG. 3 an axial section through a 3D vertical NAND flash memory design, wherein different material areas adjoining each other are depicted with different hatchings;

FIG. 4 schematically a cross-sectional view of a region of interest volume of the sample to be investigated including schematically sketches of the electron beam/sample interaction and X-rays emanating from respective interaction areas of such volume;

FIG. 5 in depictions similar to that of FIG. 4 a dependence of the size of an electron beam/sample interaction volume on the energy of the probing electrons;

FIG. 6 in depictions similar to that of FIG. 5 a dependence of the interaction volume size on the atomic number of a sample element being present in such interaction volume;

FIG. 7 schematically depictions of a sequence of FIB-SEM scans of a semiconductor sample embodied as a memory cell capacitor, e.g. a part of a vertical NAND design, wherein in the sequence from left to right which is part of the investigation method an electron beam/sample interaction volume moves from an upper layer where the memory cell capacitor is located to a bottom substrate layer;

FIG. 8 in a depiction similar to FIG. 4 a Monte-Carlo simulation of an electron beam/sample interaction volume which may be part of a post-processing step of the investigation method with from top to bottom increasing electron beam energy, wherein in the lowest depiction of FIG. 8 also an X-ray path is depicted;

FIGS. 9 to 12 schematic representations of region of interest volumes at vertical (FIGS. 9 and 10) and horizontal (FIGS. 11 and 12) boundary lines between lighter and heavier material;

FIG. 13 in a representation similar to FIGS. 9 to 12 a comparison between a region of interest volume in lighter and heavier material with identical probe electron energy;

FIG. 14 a schematic representation of a composite approach to approximate a region of interaction volume as a superposition of a lighter material volume part and a heavier material volume part at a vertical boundary;

FIG. 15 an image of a SEM scan through a semiconductor sample layer depicting a central carbon region limited by two adjoining tungsten regions;

FIG. 16 results of the investigation method using the investigation device of FIG. 1 regarding a tungsten/carbon boundary region on the left hand side of FIG. 15; and

FIG. 17 results of the investigation method using the investigation device of FIG. 1 regarding a carbon/tungsten boundary region on the right hand side of FIG. 15.

### DETAILED DESCRIPTION

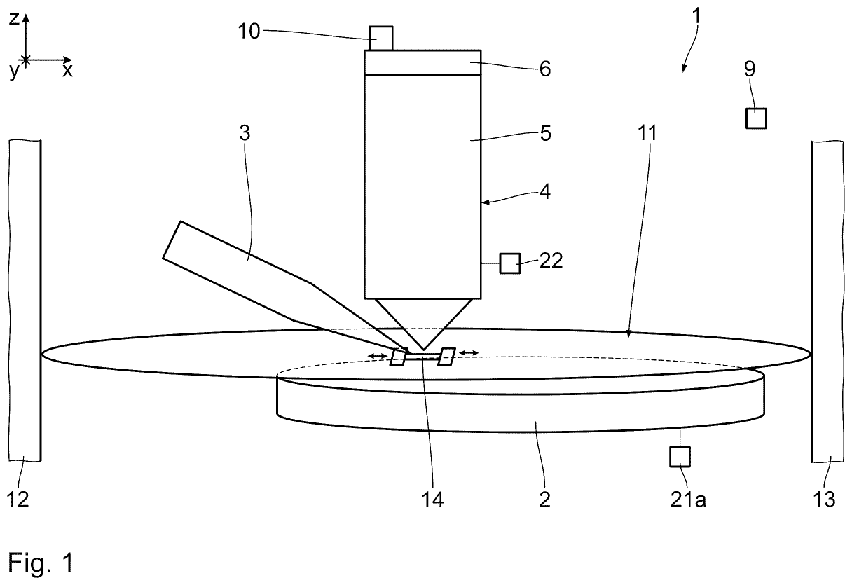

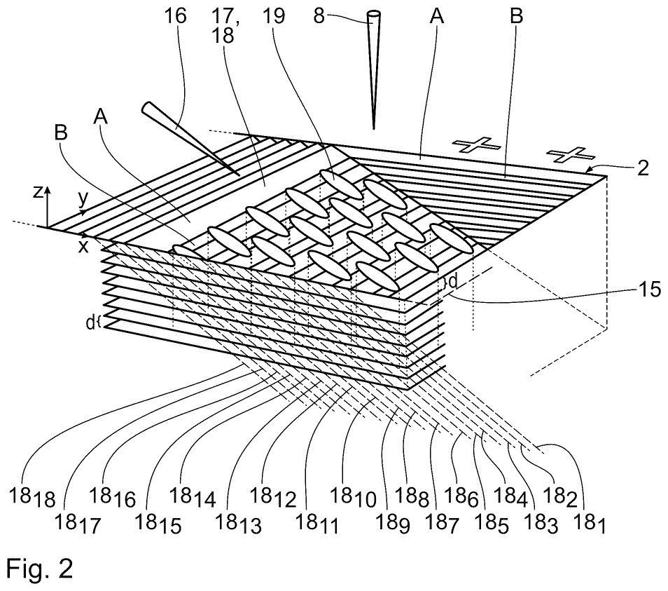

FIG. 1 shows schematically an investigation device 1 which is designed to investigate a semiconductor sample 2 layer by layer using focused ion beam (FIB) etching and X-ray spectroscopy. The investigation device 1 includes a focused ion beam (FIB) source 3 and a scanning electron microscope (SEM) 4 including an electron optics 5. Further, the investigation device 1 includes an X-ray detection device 6 detecting X-rays 7 (compare FIG. 4) emanating from the sample 2 produced by probe electrons 8 (compare FIGS. 2 and 4) of the SEM 4. Further, the investigation device 1 comprises a computer 9 to perform a post-processing of a detection signal obtained by the X-ray detection device 6.

The X-ray detection device 6 includes an X-ray spectrometer 10 schematically shown in FIG. 1. With the X-ray spectrometer 10 of the X-ray detection device 6, a wavelength-dependent X-ray detection is possible.

Further shown in FIG. 1 is a stop 11 to delimit a region of interest on the sample 2.

The sample 2 is located in an investigation chamber which is delimited by chamber walls 12, 13.

The stop 11 defines a process window 14 which is, as is schematically shown in FIG. 1, may be delimited by movable stop parts.

FIG. 2 schematically depicts a geometry of the sample 2 on the one hand and an investigation geometry of the investigation device 1 on the other. A Cartesian xyz coordinate system of FIG. 2 corresponds to that shown in FIG. 1.

The sample 2 has an initial bulk sample surface plane 15 which is located parallel to the xy plane. The electron beam from the SEM 4, i.e. the probe electrons 8, probes the sample 2 under 90° measured from the initial bulk sample surface plane 15. Further, the X-ray detection device 6 detects the X-rays 7 under 90° measured from the initial bulk sample surface plane 15. In other words, the SEM probe direction on the one hand and the X-ray detection device detection direction coincide or run parallel to each other.

An FIB 16 produced by the FIB source 3 etches the sample 2 in an etching plane 17 which includes an angle of 36° with the xy initial bulk sample surface plane 15. Such angle may be in the range e.g. between 20° and 40°.

FIG. 2 shows the momentary situation of an investigation method using the investigation device 1 where an initial layer 18, 181 to be investigated of the semiconductor sample 2 is prepared via the FIB 16. A surface plane of such initial layer 18 coincides with the momentary etching plane 17.

Due to the fact that the etching plane 17 runs under an angle to the initial bulk sample surface plane 15, alternating elementary layer structures of a first element A and of a second element B within the sample 2 are present along the initial layer 18. These A/B/A . . . elementary layer structures run parallel to the initial bulk sample surface plane 15. Further, NAND structures 19 with cylindrical boundaries having cylindrical axes running parallel to the z axis are cut at an angle within this initial layer 18. Due to the inclination of the etching plane 17 to the z axis such cylinder cuts result in elliptical contours of the NAND structures 19.

After the layer preparation, a surface area of a region of interest volume 20 which is shown dashed in FIG. 4 and has a drop shaped form is aligned with an object field 21 of the SEM 4. The region of interest volume 20 is that volume wherein the electron/sample interaction takes place which is detected and analyzed during the investigation method. The object field 21 runs parallel to the xy plane. The actual tilt between the sample layer surface and the initial bulk sample surface plane is omitted in FIG. 4.

An electron energy of the electron beam 8 of the SEM 4 is adjusted and the region of interest volume 20 is probed within the object field 21 with the electron beam 8. The X-rays 7 emanating from the aligned region of interest volume 20 are detected via the X-ray detection device 6.

Subsequently, a post-processing of a detection signal obtained during the previous detection step is performed to spatially deconvolute the detection signal into a structure signal attributed to a structure within the region of interest volume 20 as is described in more detail later on.

After that, a next layer 182 of the sample 2 is prepared. Such next layer 18₂ has a further sample surface below the previously etched sample surface. Such preparation of the next layer 18₂ is done by etching the further sample surface of the next layer 18₂ via etching of the sample 2 with the respectively aligned focused ion beam 16. Those steps aligning to post-processing are repeated until layer by layer investigation of a volume of interest of the sample 2 is completed. Subsequent layers 18₃ to 18₁₈ being results of such step repeating are further shown in FIG. 2. The layer thickness is defined by the distance between neighboring layers 18ᵢ, 18ᵢ₊₁. Such layer thickness results in an effective cutting depth d along the z direction which also is depicted layerwise in FIG. 2.

The number of layers 18; may range between 2 and 1000, such as between 2 and 500 or between 2 and 100.

The investigation device 1 includes an alignment unit 21a to align a surface area of the region of interest volume 20 of the sample 2 with the object field 21 of the investigation device 1 which may be defined by the process window 14. In FIG. 1, such alignment unit 21a is depicted schematically being effective on the sample 2. By help of the alignment unit 21a, a translation and/or tilting movement of the sample 2 relative to the object field 14 of the investigation device 1 is possible via at least three degrees of freedom. Dependent on the embodiment of the alignment unit 21a, such alignment is possible via four, five or six degrees of freedom.

Further, the investigation device 1 includes an adjustment unit 22 (also compare FIG. 1) to adjust an electron energy of the electron beam 8 of the SEM 4. Such adjustment may be done via controlling an electron accelerating voltage within the electron optics 5.

The FIB source 3, the SEM 4, the detection device 6 including the spectrometer 10, components of the stop 11, the alignment unit 21a and the adjustment unit 22 are in signal connection with the computer 9 which also acts as a control unit to control the steps of the investigation method.

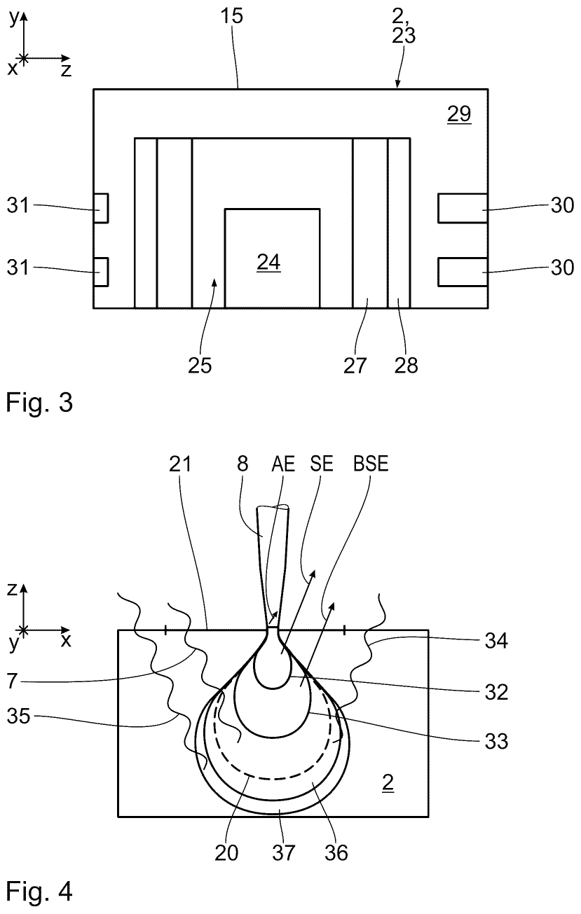

FIG. 3 schematically depicts an example of a structure 23 within the semiconductor sample 2. Again, a Cartesian xyz coordinate system of FIG. 3 corresponds to that shown in FIGS. 1 and 2. Such structure 23 may be embodied as a 3D V-NAND structure. Such structure includes a cylindrical SiO₂ core 24 having a diameter d₁. Such core 24 is surrounded by a sleeve 25 of polysilicon which may be doped to establish a transistor device. A top of the sleeve 25 is embodied as a cover 26. A sleeve thickness of the sleeve 25 is denoted by d₂ in FIG. 3. A height of the cover 26 is denoted by h₁ in FIG. 3.

The sleeve 25 is surrounded by a further SiO₂ sleeve 27 with thickness d₃ which again is surrounded by a further Si₂N₃ sleeve 28 with thickness d₄. The resulting assembly 24 to 28 constitutes a plughole in a SiO₂ bulk material volume 29. At radial edges of this bulk volume 29 further tungsten enclaves 30, 31 with different radial extensions are located. A height difference between the sleeve cover 26 and the upper ones of the enclaves 30, 31 is denoted by h₂ in FIG. 3. A z extension of the enclaves 30, 31 is denoted by t₁ in FIG. 3. A z distance between adjacent enclaves 30 and 31, respectively, is denoted by t₂ in FIG. 3.

A typical thickness of the sleeve walls d₂, d₃ and/or d₄ is in the range of 10 nm.

A distance between the enclaves 30, 31 and the outermost sleeve 28 is denoted by d₅ in FIG. 3.

Measurement quantities to be specified via an investigation method carried out by the investigation device 1 are the structural dimensions d₁ to d₅, h₁, h₂, t₁, t₂ and/or the materials (atom types, elemental types, elemental compositions types) and/or material compositions and/or material distributions of the structural components 24 to 31 and/or a dopant quantity within one of those components 26 to 31.

FIG. 4 schematically shows interaction processes related with the probing of the sample 2 with the electron beam 8. From a direct surface interaction at the layer surface within the object field 21 where the electron beam 8 hits the sample 2, Auger electrons AE result having discrete energies which are directly attributed to respective elements of the materials of the structures within the sample 2.

From a first drop-like volume part 32 of the region of interest volume 20 which is located beneath the interaction surface, secondary electrons SE are emitted carrying topographical information of the surface structures within this volume part 32.

From a further drop-like volume part 33 which is located below the SE volume part 32 and which represents a next interaction path length between the probe electrons of the electron beam 8 and the sample 2, backscattered electrons BSE are emitted, whose energy reveals information regarding the atomic number of the elements contained within the volume part 33 and further phase difference information.

From the further larger drop-like region of interest volume 20 representing a next interaction path length between the probe electrons of the electron beam 8 and the sample 2, characteristic EDX X-rays 7 having wavelengths which are attributed to an atomic/elemental composition within this region of interest volume 20 emanate. The depth of such region of interest volume 20 depends on the electron energy within the electron beam 8 on the one hand and further depends on the atomic number of the elements being present within the region of interest volume 20.

Further radiation 34 (Bremsstrahlung) and 35 (cathodoluminescence) emanates from further drop-like shells 36, 37 beneath the region of interest volume 20. This further radiation 34, 35 also may be detected and analyzed within the investigation device 1 but is not of particular relevance in the further discussion.

FIG. 5 exemplifies the dependence of the size of the region of interest volume 20 on the energy of the electrons of the electron beam 8. The three examples of FIG. 5 are given for the same element to be probed.

FIG. 5 shows on the left a small region of interest volume 20 resulting from low accelerating voltage set with the adjustment unit 22.

In the middle of FIG. 5, a larger region of interest volume 20 is depicted resulting from medium accelerating voltage of the adjustment unit 22.

On the right of FIG. 5, a large region of interest volume 20 is shown resulting from high accelerating voltage of the adjustment unit 22.

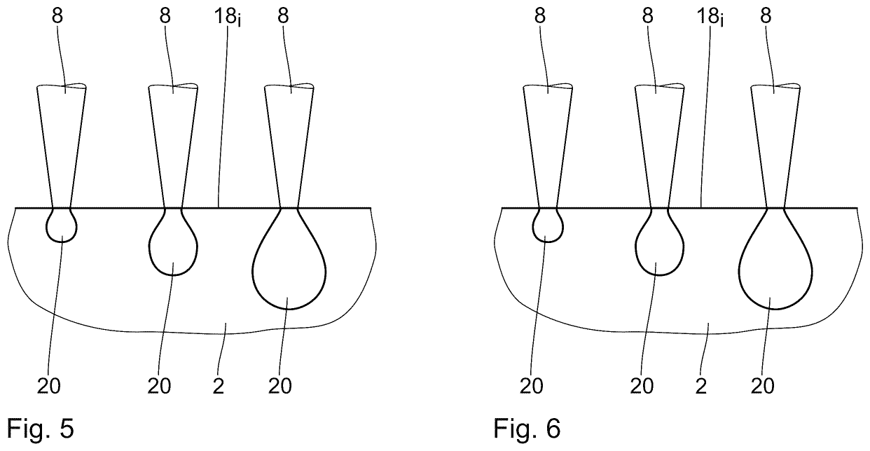

FIG. 6 shows a dependence of the size of the region of interest volume 20 on the atomic number of an element of the probed sample structure.

On the left of FIG. 6, a small region of interest volume 20 is shown resulting from probing an element with high atomic number with a given e.g. medium accelerating voltage.

In the middle of FIG. 6, a larger region of interest volume 20 is shown, resulting from the probing of an element with the medium atomic number with the same accelerating voltage.

On the right side of FIG. 6 a large region of interest volume 20 is shown resulting on the probing of an element with low atomic number with the same electron accelerating voltage.

Accordingly, also a size of the region of interest volume 20 may be used as an indicator for an elemental composition present within the sample to be investigated.

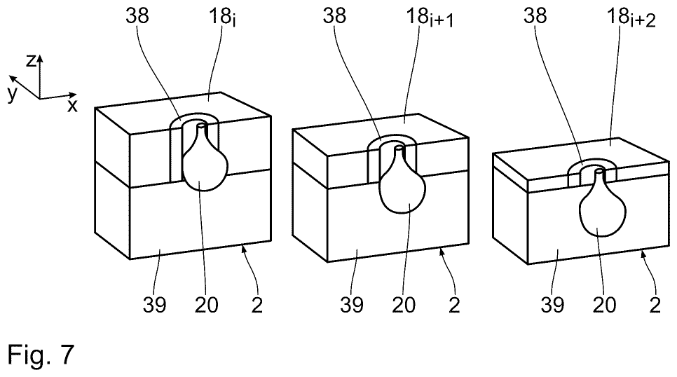

FIG. 7 shows an ongoing FIB-SEM layer by layer scan of a sample structure being exemplified as a sleeve 38 according to one of the sleeves 25, 27, 28 described above with reference to FIG. 3.

On the left side of FIG. 7, the situation after preparing e.g. an initial layer 18; to be investigated (compare also the above description with respect to FIG. 2). Shown is the region of interest volume 20, i.e. the interaction volume within the sample 2 between the electron beam (not shown in FIG. 7) and the sample material. Such region of interest volume has a quantitative volume X.

An intersection point of the electron beam 8 into the first layer 18; is denoted by y. A location x as an exemplified location within the total region of interest volume 20 from which radiation to be examined emanates also is shown on the left of FIG. 7. From this location x, X-rays to be detected by the detection device 6 emanate within a detection cone 22.

The region of interest volume 20 within the first layer 18; includes parts from an inner cylinder material of the sleeve 38, parts of the sleeve 38 itself, parts of material radially surrounding the sleeve 38 and further parts of a substrate material 39 below the sleeve 38.

The middle depiction of FIG. 7 shows the situation after preparing another layer 18ᵢ₊₁ to be investigated. Accordingly, the region of interest volume 20 which in this case has not altered in its size has shifted towards the substrate material 39. Only a smaller part of the region of interest volume 20 in the middle of FIG. 7 now includes material of the inner cylinder or material of the sleeve 38.

On the right side of FIG. 7 the situation after preparation of the next layer 18ᵢ₊₂ is shown. Now, the region of interest volume 20 further has shifted towards the substrate material 39. Only a small part of this region of interest volume 20 includes material of the center cylinder. Almost no material of the sleeve 38 is included within the region of interest volume 20 when probing the layer 18ᵢ₊₂.

Consequently, a layer by layer preparation 18ᵢ, 18ᵢ₊₁ and a careful comparison of the detected rays enables a deduction of a structural and/or material composition of the sleeve structure within the sample 2 of FIG. 7.

The interaction volume parts 32, 33 within the region of interest volume 20 can be understood as volumes exhibiting kernel values of a point spread function. Such kernel values are associated with interaction parameters, for example with the energy of the incoming electron beam 8 via the definition of a restrictive point spread function with a kernel value which depends on the kind of interaction between the electron beam 8 and the sample and by defining a spatial variable representing a volume dependent physical sample property and by defining an imaging property of the emitted electron beams and/or radiation to be measured from the region of interest volume 20. A deduction of a structural and/or material composition for example of the sleeve structure within the sample 2 is possible by determining a minimum divergence

min D(Mₙ∥Kₙ*V)
wherein:
Mₙ is the number of the respective measurement having different measurement properties of the electron beam 8;
Kₙ is the kernel value of the point spread function to represent the behavior of the probing electron beam 8 in a bulk of the sample 2;
V is the spatial variable representing the physical property of the sample 2 as a function of position within the sample 2. In that respect, it is referred to EP 2 557 584 A1.

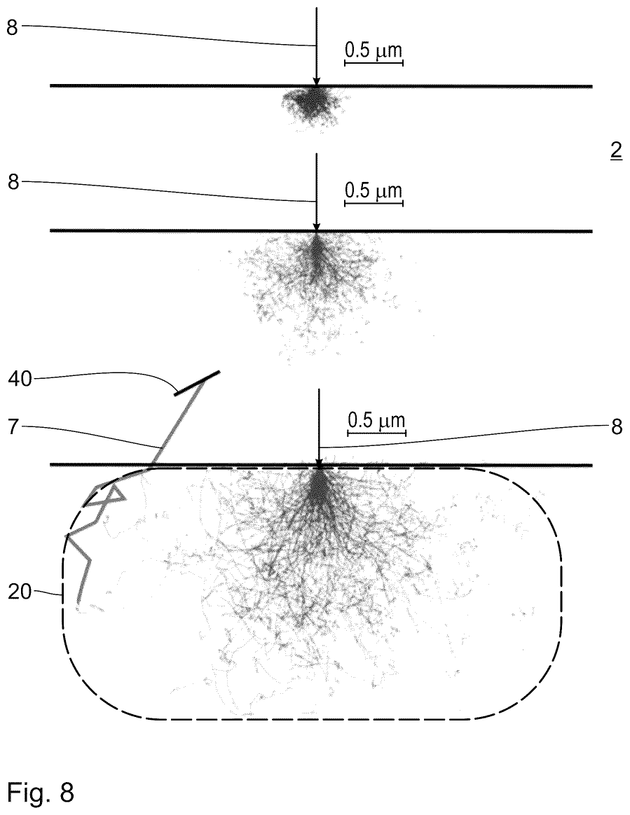

FIG. 8 shows three different results of Monte-Carlo simulations regarding the interaction between electrons from the electron beam 8 and the sample 2 within the region of interest volume 20. Shown are individual electron trajectories.

FIG. 8 above shows the simulation result using a low acceleration voltage for the probe electrons.

In the middle of FIG. 8 the situation is shown using a middle accelerating voltage and FIG. 8 below shows the situation using a high accelerating voltage. Also shown is the boundary of the region of interest volume 20. Further, in FIG. 8 below, a path of an X-ray 7 towards an X-ray detector 40 of the X-ray detector device 6 is shown.

During the post-processing of the detection signal obtained during the detection step, geometry input or other a priori condition input from further and for example preliminary measurements may be used.

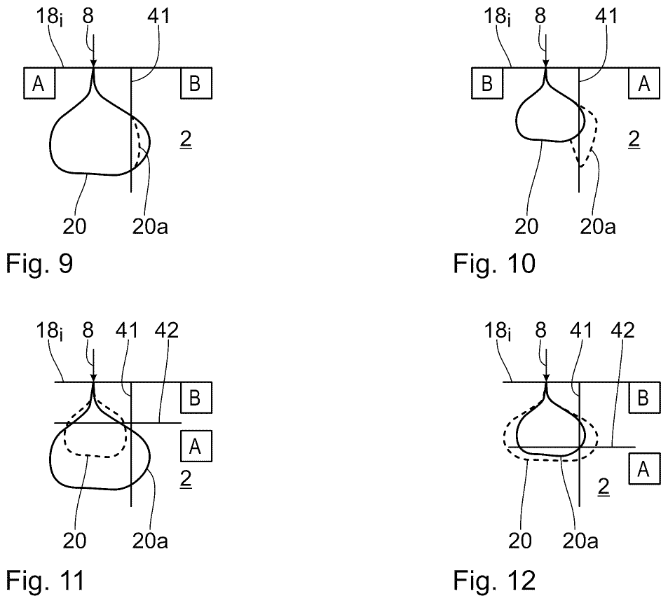

FIGS. 9 to 11 show exemplified examples for such a priori condition input. With solid lines, an initially assumed extension of the region of interest volume 20 is shown. Shown with dashed lines, a refined part of the region of interest volume 20 is shown taking into account a priori knowledge with respect to the distribution of different materials within the sample 2 to be investigated.

FIG. 9 shows the situation of a vertical boundary 41 between lighter material A and heavier material B. As explained above with respect to FIG. 6, the heavier material with high atomic number reduces the extension of the region of interest volume (dashed line 20a in FIG. 9 as compared to solid line of region of interest volume 20).

FIG. 10 shows the inverse situation wherein the main part of the region of interest volume 20 is within the heavier material B and a smaller part of the region of interest volume 20 is across the vertical B-A material boundary 41. As within the lighter material A, a larger part of the region of interest volume 20 is present, the dashed real resulting region of interest volume (line 20a in FIG. 10) is larger than the initially assumed region of interest volume.

FIGS. 11 and 12 show the situation of a horizontal layer boundary 42 between materials A (light) and B (heavier).

In the FIG. 11 situation, a top layer of heavier material B is separated via the horizontal boundary 42 from a bottom layer of lighter material A. The region of interest volume 20 expands when entering the lighter material A to its actual shape 20a.

In the FIG. 12 situation, the top layer is of the lighter material A and, separated by horizontal boundary 42, the lower layer is of the heavier material B. Accordingly, the nominal region of interest volume 20 is compressed to the actual region of interest volume 20a when hitting the heavier material B.

FIG. 13 shows in a depiction similar to that of FIGS. 9 to 11 a comparison between region of interest volume 20a in lighter material A and region of interest volume 20B in heavier material 20B assuming identical other conditions of the incoming electron beam 8. The region of interest volume 20A is more extended as compared to the region of interest volume 20B which is more compressed. Such compression may result in a faster spreading of the compressed region of interest volume 20B beneath the sample surface (surface of respective layer 18i).

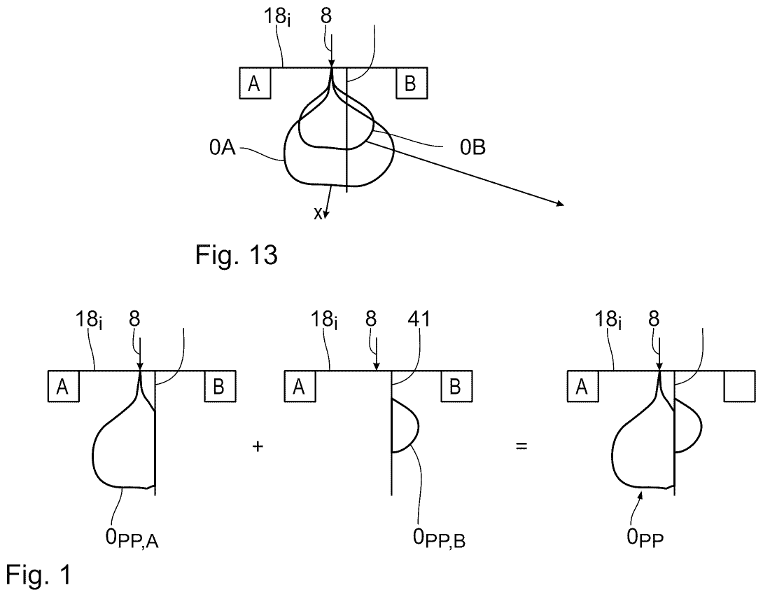

FIG. 14 shows how starting from the knowledge of a position of a vertical boundary 41 comparable to that of FIGS. 9 and 10, and further starting with the knowledge of the extension of the region of interest volumes 20A (lighter material) and 20B (heavier material) an approximation of a composite region of interest volume 20_{PP} can be calculated in a post-processing step of the investigation method.

FIG. 14 is depicted as an equation.

On the left hand side, two “terms” are shown. For such a priori condition input a region of interest volume contributions 20_{PP,A} of the lighter material A on one side of the boundary 41. The second “term” on the left hand side of the equation of FIG. 14 shows a region of interest volume contribution 20_{PP,B} of the heavier material B on the other side of the vertical boundary 41.

The right hand side of the equation shown in FIG. 14 shows the resulting composite region of interest volume 20_{PP} being a sum of region of interest volume contributions 20_{PP,A} and 20_{PP,B}.

According an example of the disclosure, the composition is described by a superposition of homogeneous material scattering cross-sections. According the disclosure, such simplified model composition enables a traceable optimization. According another example, the density of the respective material A, B to be estimated does not influence a basic shape of the region of interest volume 20. Such approach can be used as an alternative to a Monte-Carlo simulation approach (compare FIG. 8 above).

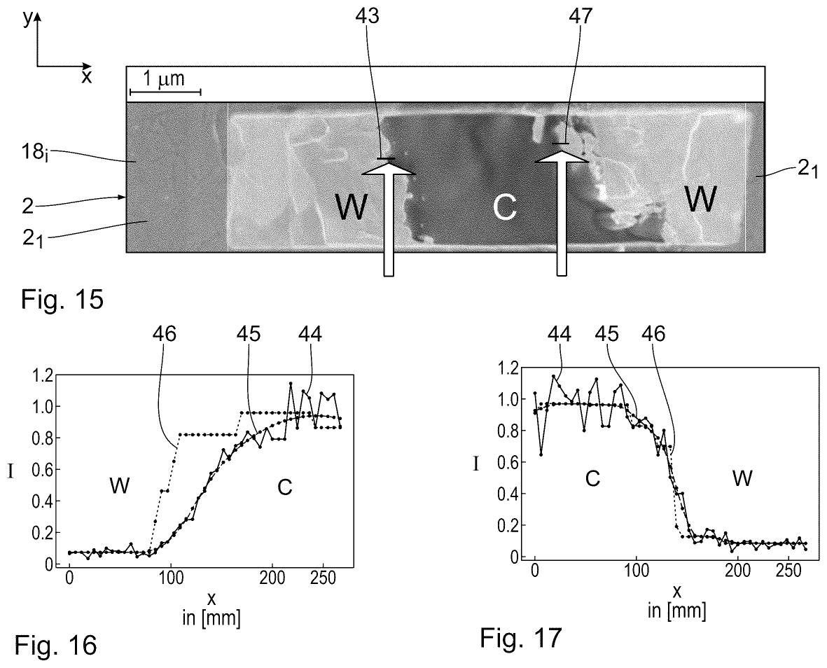

FIG. 15 shows a conventional SEM picture of a prepared layer 18; of an exemplified example 2 as the result of a conventional SEM scan. The total horizontal width of the shown SEM scan is approximately 6 μm. FIG. 15 shows this layer 18; from above, i.e. the xy plane of the previously introduced xyz coordinate system coincides with the drawing plane. Shown is a surrounding matrix material 21 which may be SiO₂. In the center of FIG. 15, from left to right a material sequence tungsten (“W”), carbon (“C”) and again tungsten (“W”) is shown. The layer 18; shown in FIG. 15 is an example for an elemental structure to be investigated within the sample 2.

FIG. 16 shows detection and post-processing results of the investigation method according the disclosure, performed with the investigation device 1 done at a W/C SEM/EDX scan line 43 which is indicated at the W/C boundary in FIG. 15. The total length of the scan line 43 shown as the nm-abscissa in FIG. 16 is 250 nm.

The measurement was done with a probe electron energy of approximately 3 keV of the electron beam 8. A measured EDX intensity I in an X-ray bandwidth corresponding to boundaries [270 eV, 290 eV] is shown as line 44 in FIG. 16.

During the post-processing step of the investigation method according the disclosure, from this measured EDX intensity I 44 a convolved EDX intensity I 45 is produced where riffles of the measured EDX intensity I 44 are smoothed out.

FIG. 16 further shows a spatially deconvolved EDX intensity I 46 which is the end result of the post-processing step of the investigation method. Unlike the measured EDX intensity I 44 and the convolved EDX intensity I 45, the deconvolved EDX intensity I 46 shows a steep rise at the W/C boundary position along the W/C scan line 43. Such steep rise corresponds to a resolution with respect to the reproduction of the W/C boundary of approximately 20 nm.

FIG. 17 shows the result of an X-ray detection via a C/W SEM/EDX boundary scan line 47 shown in FIG. 15. The total length of the scan line 47 again is about 250 nm. FIG. 17 shows the situation when detecting tungsten again using a probe electron energy of the 2 keV of the electron beam 8 but now detecting X-rays corresponding to an EDX energy in the bandwidth [1760 eV, 1780 eV]. Here, an edge steepness of the measured spatial spectrum 44 of the convolved spatial spectrum 45 and of the deconvolved spatial spectrum 46 is more or less the same and also leads to a resolution of approximately 20 nm.

The ordinate of FIGS. 16 and 17 represents a normalized X-ray intensity.

A comparison of the results of FIGS. 16 and 17 shows that the spatial deconvolution of the post-processing step of the investigation method according the disclosure is beneficial for lower detected X-ray energies, attributed for example to the elements carbon (around 280 eV), nitrogen (around 390 eV), titanium (around 450 eV) and oxygen (around 530 eV).

As also discussed above, FIGS. 4 to 6 show a sketch of the interaction volume of an electron beam 8 with the material sample 2, which in this case is assumed to be homogeneous. The sketch is considered in three dimensions, a point in the volume being denoted by x∈ [symbol] ³ or y∈ [symbol] ³. A scattering cross section (electron/electron or electron/X-ray) within the interaction volume in the following analytical approach is denoted by σ_{Si}(x; y), where x is an evaluation point in the volume and y is a target point of the electron beam. The index Si may indicate the material, e.g. silicon in this case.

As also discussed above, in an example of the disclosure, a FIB-SEM configuration is used, using adestructive 3D-scanning of the sample volume by iteratively removing sample layers 18ᵢ. For this reason, the target point y∈ [symbol] ³. is also considered to be three-dimensional, compare FIG. 7.

In general, the scattering cross-section is spatially varying, which is indicated by its dependence on y, i.e. at different scan positions, the shape of the interaction volume will typically change unless a homogeneous material is scanned. Further, a fixed inclination of the sample surface 18; with the beam 8 throughout the scan, which is a parameter of the scanning device parameters and the sample/device geometry. Collectively, these device/geometry parameters will be referred to in the following analysis as d.

At a fixed scan position y′, the cross-section function is then a scalar function in three dimensions [symbol] ³ [symbol] [symbol] . The actual form of the function depends on the material density distribution ρ₁(x), . . . ,ρ_{N}(x) within the interaction volume X, i.e. the region of interest volume 20 (compare FIG. 7, left), where ρᵢ(x) denotes a material density in three dimensions, with N material species being present in the volume.

The scattering cross-section will also be parameterized by λ, i.e. the regarded X-ray energy in the EDX measurements performed with the investigation device 1.

Given these preliminaries, the measurement is formulated as

$$I ( y , λ ) = {\int }_{Ω} {\int }_{X} σ ( x , y , ω , λ ; \vec{θ} , {ρ}_{1} , … , {ρ}_{N} ) d x d ω \qquad ( 1 )$$

wherein the scattering cross-section σ acts as a spatio-angularly varying kernel that depends on the material density functions ρ₁(x), . . . ,ρ_{N}(x), i.e. the (unknown) distribution of elements/atoms in the sample and the device settings and geometry stored in the device/geometry parameters \vec{θ}. The sample and device settings are separated from the other parameters in the argument list of the scattering cross-sections (by the “;”) because they are considered to be fixed in a given experiment. The solid angle 22 (compare FIG. 7) indicates the detector geometry and w is a differential solid angle towards the detector (multiple scattering omitted).

Equation (1) generally describes a multi-modal imaging approach. According the multi-modal imaging approach, a plurality of intensities with different spectral ranges, here indicated by λ of electromagnetic radiation including X-ray radiation, are detected. Further secondary radiation, such as scattered or secondary electrons can be considered as well in the multi-modal imaging approach. The disclosure provides a method of generating an image of a sample with higher resolution by utilizing a multi-modal imaging approach and a computerized inversion of the multi-modal imaging approach. In an example, the computerized inversion of the multi-modal imaging approach is improved by utilizing prior information of the sample to be investigated, for example CAD-information or a prior known material composition of a sample. In an example, the computerized inversion of the multi-modal imaging approach is improved by utilizing material specific spectral ranges of X-rays and prior information about typical scattering cross sections. In an example, the computerized inversion of the multi-modal imaging approach is improved by using the slice- and imaging method with a FIB-SEM as described above. In the following, several examples the investigation method, utilizing the computerized inversion of the multi-modal imaging approach, are illustrated.

In the following, it is referred to the spatially varying scattering cross-section inside the interaction volume as the kernel. The vector \vec{θ} collects the device/geometry imaging parameters that influence the scattering cross-section, in particular
the electron energy of the probe electrons in the electron beam 8 (acceleration voltage) in [kV],
the beam current in the electron beam 8 in [nA],
the integration time of the detector 40 of the detection device 6 in [s],
the tilt angle of the sample layer 18; with respect to the electron beam 8 in [deg] measured e.g. with respect to the surface layer normal.

It should be noted that the kernel is vector-valued since X-rays 7 of different energy E=hv with v=c/λ are being generated upon excitation by the electron beam 8. Here, vis the photon's frequency, c the speed of light, h Planck's constant and λ the photon wavelength. For reference:

$$E = \frac{6 \text{.626} \cdot {10}^{- 34} [ kg m / {s}^{2} ] \cdot \frac{3 \cdot {10}^{8} [ m / s ]}{λ \cdot {10}^{- 9} [ m ]}}{1 / ( 6.24 \times 1 {0}^{18} ) [ Nm ]} \approx \frac{1240.387}{λ} [ eV ] \qquad ( 2 )$$

where the wavelength is given in [nm].

The kernel is, in general, unknown and depends on several parameters. Herein after, major effects and their influence on the super-resolution problem are discussed.

The underlying physical reason for the kernel is a (multiple) scattering process of the primary electrons that are being used to probe the sample FIG. 8. There are generally three scattering processes with interaction products (also compare FIG. 4):
1. electrons: upon interaction with the sample, the electrons are scattered with different underlying mechanisms, wherein the primary electrons are loosing energy in the process.
2. X-rays:
   (a) since electrons are charged objects any change of velocity or direction results in electro-magnetic radiation. This radiation has a continuous spectrum and is referred to as Bremsstrahlung.
   (b) The second source of X-rays is the ionization of atoms within the material under investigation. X-rays are generated from transitions in the inner electron shells of the material's atoms (generating pho-tons upon relaxation to the ground state). The ionization spectrum is spiky and characteristic of the material. It is also referred to as characteristic radiation. The probability of a radiative transition is given by w.
   (c) Ionized atoms can also relax via a non-radiative process called Coster-Kronig transition that results in an emitted (Auger) electron AE. The probability of a non-radiative transition is given by 1−w.
3. visible light: once the kinetic energy of the electrons is low enough, only the outer electron shells of the atoms can be excited giving rise to visible light emission known as cathodoluminescence. It is low-resolution (being emitted from a large interaction volume) but contains information on the atom species if resolved spectroscopically.

Due to the restricted detector size, not all backscattered electrons or photons can be captured. A modified kernel is limited to the collected secondary radiation and is limited to only describe for example a fraction of the X-ray photons hitting the detector 40.

In addition, currents are generated inside the material which may interact with the incoming electrons. There are also charging phenomena if the electrons cannot be “drained” quickly enough.

Since X-rays may be multiply scattered, they may also cause fluorescence, i.e. introducing a Stokes shift to the measure wavelengths. This typically results in new spectral peaks at lower energies.

The major effects from the device/geometry/imaging/sample parameters \vec{θ} are:

Excitation Energy: the energy of the electrons in the primary electron beam influences the size of the interaction volume, see FIG. 5. It is practically influenced by the acceleration voltage. A higher energy of primary electrons results in a larger interaction volume, i.e. a larger kernel, which implies a lower resolution of the EDX images/3D stacks.

Since the acceleration voltage is a device parameter of a SEM, the primary electron energy or excitation energy can
1. be adjusted, at least throughout a single SEM scan, and
2. its variation can be modeled e.g. through simulations.

Beam current and exposure time: these parameters fix the overall electron flux into the material. They are mainly responsible for the signal to noise ratio (SNR) in the measurements. In the following, a good SNR is assumed, i.e. measurements dominated by photon shot noise, i.e. Poisson noise with a large mean value.

Sample Tilt: The sample tilt influences the interaction volume since an asymmetric situation with respect to the surface normal of the sample layer 18₁ is introduced. Parts of the electrons have shorter effective paths for leaving the sample than others. The tilt angle is assumed to be fixed during a scan. Its effect therefore can be included in the simulations.

A detector efficiency and/or a detector geometry can be treated by simulation.

In other examples, other secondary radiation, such as back-scattered or secondary electrons and electromagnetic radiation below the x-ray regime can be considered as well.

The second class of effects comes from the sample composition. The main influential factor are the atom and molecule species being present in the region of interest volume 20. They influence the electron-X-ray cross sections considerably.

Material (atomic number): The shape of the region of interest volume 20 depends on the atomic number of the material. Heavier nuclei lead to smaller interaction volumes as compared to the lighter elements, see FIG. 6.

In the following, examples of the investigation method according the disclosure are given. With subsequent approximations, the mathematical properties of the optimization problem become better and the computational restrictions are lowered. In some examples, the investigation method typically relies on prior information or model based assumptions of materials or material compositions of a sample to be investigated.

Monte-Carlo simulation is an available forward model for simulating the physics of electron microscopy. Available software for Monte-Carlo simulations is well established and known.

Simplifications are used to adapt the results of Monte-Carlo simulations for the post-processing step of the investigation method.

Generally, the dependency on collection angle according solid angle Ω (compare FIG. 7) is not illustrated in the following description.

According a first example, the scattering cross section σ(x, y, λ; \vec{θ}, ρ1, . . . , ρN) is simplified according the example shown in FIG. 14. In such case, the cross sections are simplified as

$$σ ( x , y , λ , \vec{θ} , {ρ}_{1} , … , {ρ}_{N} ) \approx {\sum }_{i = 1}^{N} {σ}_{i} ( x , y , λ , \vec{θ} , {ρ}_{i} ) \cdot {ρ}_{i} ( x ) \qquad ( 3 )$$

where the spatially varying cross-section σ is described as a sum over a homogeneous cross-section σ of a single material, scaled by the local material density ρᵢ. This approximate model assumes that the X-ray generation can be considered for a single material species only. Note that the material density ρᵢ(x) may scale a characteristic X-ray generation to zero in regions where a specific material is not present.

In this case, Eq. 1 can be interpreted as a spatially varying convolution-like operation:

$$I ( y , λ ) = {\int }_{x} {\sum }_{i = 1}^{N} {σ}_{i} ( x , y , λ , \vec{θ} , {ρ}_{i} ) \cdot {ρ}_{i} ( x ) dx \qquad ( 4 )$$

According the disclosure, eq. 4 can be solved for the functions ρᵢ. In the discretized setting according the first example, the optimization problem can be written

$$arg {min}_{{ρ}_{1} , {…ρ}_{N}} ‖ I - {\sum }_{i} {A}_{i} {ρ}_{i} ‖ + priors \qquad ( 5 )$$

where the matrices Aᵢ are discretized versions of the linear operators in Eq. 4 for the material cross sections ρᵢ, ∥·∥ is a norm to measure the deviation of the predicted spectra due to the material densities ρi and the measurements I (E²=I), and “priors′” is a generic term for a-priori conditions imposed on the perturbed material densities ρᵢ.

Equation (5) may be interpreted to refer to a limit situation in which an excitation enables photons to just reach the detector.

Computing the region of interest volume 20 and the resulting intensity I(y, λ) a suitable SNR, may involve long dwell times, for example in the order of minutes for a single point y, which would have to be repeated for every FIB-SEM sample lo-cation in the 3D (layers 18ᵢ, 18₁₊₁, . . . ) data stack (on the order of e.g. a million samples). The effort can be reduced by exploiting symmetries in the sample geometry and/or the scanning setup, parallel computations, etc.

A further example of investigation method according the disclosure is as follows: starting point is a known nominal design, e.g. provided by a CAD file and material data, with its realization slightly deviating from the perfect model prescription. In this case, using significant prior knowledge being introduced at small actor deviations from a prior model in the real sample, the inversion of Eq. 1 may be computed directly.

Further, hereinafter more approximate schemes are presented that may also offer a broader applicability by involving less prior knowledge.

An example for such further approximation consists in ignoring material inhomogeneities in the computation of the σᵢ, Eq. 4. In particular, this ignores the effect of material boundaries in determining the shape of the cross-section functions.

This model still follows Eq. 4. However, the computation used to determine the cross-section functions σᵢ is now independent of the sample, the cross section shape becomes spatially invariant.

The model of Eq. 1 therefore becomes

$$I ( y , λ ) = {\int }_{x} {\sum }_{i = 1}^{N} {σ}_{i} ( y - x , λ , \vec{θ} , {ρ}_{i} ) {ρ}_{i} ( x ) dx \qquad ( 6 )$$

which is a 3D spatial convolution for every spectral channel λ. This enables fast FFT-based implementations of the 3D convolution. In addition, there are no registration requirements between simulation/reconstruction and experimental measurement. The model can be used with the optimization scheme of Eq. 5.

In addition to reducing the preparatory simulation time, the sample composition no longer needs to be known in advance. The approximations are a) the interaction volume does not deform when approaching a material boundary, and b) X-ray absorption between generation site and detector ignores the spatial structure of the sample, instead the absorption cross section of the photon-emitting material is assumed to hold throughout the volume (excluding free-space between sample and detector, which is modeled correctly).

The adverse effects may be partially compensated by prior information which is discussed elsewhere here.

A real detector does not see ideal X-ray transition lines being infinitely thin and which could easily be differentiated in a spectrum, but has a limitation on the line width it can resolve. This is called the spectral response of the EDX sensor. The spectral response may well be described by a Gaussian of varying variance for different detection energies. The result of the limited spectral response may be that nearby X-ray transition peaks blur into one another, a process referred to as spectral convolution.

The actually recorded spectral intensity are therefore given by using either model Eq. 4 or Eq. 6 for the emitted X-ray radiation I(y, λ) in addition a Bremsstrahlung component E_{bs} (y, λ) that previously has been ignored is now introduced:

$${I}_{c} ( y , λ ) = \int I ( y , {λ}^{′} ) r ( λ , {λ}^{′} ) d {λ}^{′} + \int {E}_{bs} ( y , {λ}^{′} ) r ( λ , {λ}^{′} ) d {λ}^{′} \qquad ( 7 )$$

where I_{c}(y, Δ) is the recorded photon count for energy λ at sample position y and r(λ, λ′) is the energy-dependent spectral response function of the sensor. The integral of Eq. 7 is split into two parts that are due different physical processes in order to be able to refer to them subsequently.

The process of unmixing the peaks is then known as spectral deconvolution.

An approach may be a direct inversion of Eq. 7. However, the data are usually very noisy and the kernel attenuates high frequencies, making the inversion unstable, amplifying noise. In practice, the ill-conditioning prevents a high spectral resolution from being achievable. Further examples of solving eq. (7) according the disclosure are illustrated in the following.

Integration into 3D Optimization: By analytically combining Eq. 7 with one of the models Eqs. 4 or 6 and derive an optimization approach as in Eq. 5, a direct computational approach for the post-processing deconvolution step is possible with the expense of relatively high computation power.

Deconvolution with Known Materials I: Known Emission Line Energies: Here, it is assumed that the elements present in the sample are known. In this case, there is a discrete number L of X-ray transition lines λ′ᵢ=1 . . . L for the emitted radiation, plus a continuous Bremsstrahlung background, that is ignored in the first step of the derivation. Then, the first integral of Eq. 7 reduces to a sum:

$${I}_{c} ( y , λ ) = {\sum }_{i = 1}^{L} I ( y , {λ}_{i}^{′} ) r ( λ , {λ}_{i}^{′} ) \qquad ( 8 )$$

Since the measured counts I_{c}(y, λ), the spectral response functions r of the sensor and the X-ray transition lines λ′ᵢ are known, it is possible to compute the coefficient I(y, λ′ᵢ)=: eᵢ (y) where the latter notation emphasizes that the quantity is simply a scalar coefficient for the particular Gaussian r(λ, λ′ᵢ)=: r(λ) of the sensor response centered at the wavelength λ′ᵢ. Eq. 8 therefore describes a linear system at every sample location y. The linear system only covers the spectral, i.e. the energy dimension. It can be seen as fitting the measured spectrum with a set of known emission peaks. Writing it with the reduced notation and ignoring the spatial y-dependence makes this more obvious:

$$i ( λ ) = {\sum }_{i = 1}^{L} {e}_{i} {r}_{i} ( λ ) \qquad ( 9 )$$

Since a typical spectrum has more A samples than the L X-ray transition lines, the linear system has to be solved in a least-squares fashion which can be written as

$$arg {min}_{e} {‖ R \cdot e - i ‖}_{2}^{2}$$

where bold symbols are vectorial versions of the quantities introduced above. The matrix R contains the sampled sensor response functions r in its columns. It should further be exploited that it is known that the values eᵢ≥0. This can be done by adding the optimization constraint e≥0, and solving using a quadratic programming solver instead of performing an unconstrained least-squares fit.

So far, the continuous Bremsstrahlung background (Eq. 7, second term) has been ignored. Thus, directly applying Eq. 10 will yield a biased estimate, because the Bremsstrahlung component will be attempted to be fit by a discrete set of broadened emission X-ray transitions.

According a further example, the optimization formulation of Eq. 10, however, also makes it straightforward to include additional information. The Bremsstrahlung component is modeled as a smooth function that is super-imposed on the broadened emission lines. The Bremsstrahlung is represented by a linear combination of K basis functions that are convolved with the spectrally varying sensor response function r(λ, λ′):

$${e}_{bs} ( λ ) = {\sum }_{k = 1}^{K} {b}_{k} \int {ϕ}_{k} ( λ ) \cdot r ( λ , {λ}^{′} ) d {λ}^{′} ,$$

where bₖ are the coefficients and ϕₖ(λ) are the basis functions for the Bremsstrahlung background. Thus, equation 10 can be written as:

$$arg {min}_{e , b} {‖ R \cdot e + Φ \cdot b - 1 ‖}_{2}^{2} \qquad ( 11 )$$

The matrix Φ contains the discretized convolved Bremsstrahlung basis functions in its columns and vector b collects the coefficients br. For the choice of Bremsstrahlung basis different expansions are possible, standard bases include polynomial bases.

Another possibility are truncated power law spectra that have been advocated to be suitable for low [keV] ranges. Such truncated power law spectra are known to the expert from applications in astronomy and astrophysics. Another flexible option is the simulation of a large number of Monte-Carlo Bremsstrahlung spectra and their statistical reduction into a PCA (principle component analysis) basis. Such reduction may help to drastically reduce the amount of data to be processed. Thus, the computing time could be reduced significantly.

In a variant, a deconvolution with Unknown Materials, but given a Super-Set of Candidate Elements is performed. This setting is an extension of the previously discussed method. It is assumed that a super-set of elements of interest to a specific application is known: not all such elements have to be present in a particular sample. However, there should be no elements missing from the elemental super-set. In this case, there is an instance of variable selection and fitting for which e.g. non-linear total variation based noise removal algorithms are known to the expert, i.e. an algorithm has to choose the right elements and apply a fit as in Eq. 11. The standard method of choice is a regression shrinkage and selection algorithm known as the LASSO. It can be implemented by L1-regularization. The optimization method than reads:

$$arg {min}_{e , b} {‖ R \cdot e + Φ \cdot b - i ‖}_{2}^{2} + γ {‖ e ‖}_{1} \qquad ( 12 )$$

where γ is a tuning parameter that forces sparser solutions (i.e. solutions with more zero coefficients) when chosen larger. Alternative solutions are L₀ regularization, which however, results in a computationally expensive exhaustive search procedure.

A deconvolution with basic materials may be performed using known emission line energies and their relative proportion. According to the technique proposed in the previous paragraph the algorithm chooses arbitrary ratios of X-ray emission lines in order to fit the data. In reality, these ratios are not arbitrary but follow certain distributions that are difficult to quantify for elements occurring in arbitrary mixtures and over different spatial structures. For this reason, some flexibility for the algorithm may be introduced to choose less probable peak ratios if better data fits can be achieved. This excludes the straightforward extension of the above scheme: the utilization of a linear combination of the individual emission peak responses rᵢ belonging to a common element that can e.g. be extracted from the scan or simulation of a homogeneous bulk material. Let us assume the elemental response j can be represented by \hat{r}ⱼ(λ)=Σᵢaᵢ^{j}rᵢ^{j}(λ), where the element j is indicated as a super-script.

Instead of enforcing a hard constraint that the aᵢ may be assumed as a vector that is pointing into a likely direction of co-variation for the coefficients of the individual emission line responses (part of the coefficient vector e in Eq. 10 and its variants). This may be done by encouraging solutions are close to the subspace of expected coefficient variation.

### Let

$$P = ( \begin{matrix}{α}_{1}^{1} & 0 & … & 0 \\ {α}_{2}^{1} & 0 & … & 0 \\ ⋮ & 0 & ⋱ & 0 \\ {α}_{{N}_{1}}^{1} & 0 & … & 0 \\ 0 & {α}_{1}^{2} & … & 0 \\ 0 & ⋮ & ⋱ & 0 \\ 0 & {α}_{{N}_{2}}^{2} & … & 0 \\ 0 & 0 & … & {α}_{1}^{M} \\ 0 & 0 & ⋱ & ⋮ \\ 0 & 0 & … & {α}_{{N}_{M}}^{M}\end{matrix} ) \qquad ( 13 )$$

contain the individual elemental coefficient variation directions in its columns. Here, M elements are indicated with N1, N2, . . . , NM emission lines each. The aᵢ^{j} are the corresponding coefficients.

$$Π = {P ( {P}^{T} P )}^{- 1} {P}^{T} \qquad ( 14 )$$

is an orthogonal projector for the subspace encoded in matrix P. The optimization problem, Eq. 10, may be re-written with an additional regularizer that imposes a penalty on solutions that are far from the subspace of expected coefficient variations as follows:

$$arg {min}_{e , b} {‖ Re + Φ b - i ‖}_{2}^{2} + λ {‖ Π e - e ‖}_{2}^{2} \qquad ( 15 )$$

Eq. 15, as compared to Eqs 10-12, enforces a certain elemental response with different a priori approximately known relative peak heights for individual elements. It is therefore much more stable against an accidental switch of emission lines. Consider the case of a Tungsten/Silicon mixture. The W M5−N6+7 (1773.60 [eV]) and the Si K−L2+3 (1739.70 [eV]) X-ray lines are spectrally closer to each other than the spectral response width of a typical SDD detector (e.g. 122 [eV] FWHM at Mn Kα) which may be used in the X-ray detection device 6. Thus, a single peak is observed which could consist of either Si, W, or both. It is difficult to tell the elements apart by observing the single peak. However, W has the additional isolated group of peaks W M4−N2+M5−N3 (1380.00 [eV] and 1383.90 [eV]), the presence and height of which indicate a) the presence of W and b) approximately its relative amount. Eq. 15 exploits this reasoning whereas peaks are fit individually for Eq. 10 and variants which can lead to elemental misattribution.

Standard Priors: The use of prior information (a priori conditions) is of desirable. It is here referred to the terms shortened as “priors” in Eq. 5. Such priors may include smoothness priors such as L2-norms on the gradient of a reconstructed function (material density), edge-preserving priors such as Total Variation known from non-linear total variation based noise removal algorithms and small coefficient priors such as Tikhonov regularization. It is desirable to use these or similar priors in the reconstruction scheme according the disclosure.

Different modes in multi-modal electron microscopy have a different spatial resolution and different intensity properties. As discussed above, the multi-modal imaging approach is not limited to the analysis of spectrally resolved X-ray intensities. As an example, intensity images based on back-scattered electrons (BSE) are differentiated by their kinetic energy from secondary electrons (SE). BSE-intensity contrast is dominated by the number of protons of the element of the sample (Z-contrast). The contrast further depends on the beam energy.

Thus, edges in BSE intensity images (possibly also, but less suitable, in SE images) may be used as indicators of chemical contrast.

Further, BSE have a smaller interaction volume in all three space dimensions and offer higher spatial resolution.

Simultaneous BSE images may give suitable additional information that can increase the robustness of the proposed super-resolution, multi-modal imaging scheme. SE/BSE images may be used as guide images for image cleaning. SE/BSE images may be proposed as guide images to clean and increase the resolution of EDX material maps (using joint bilateral filtering). Similarly, in STEM (scanning transmission EM), HAADF (High-angle annular dark-field imaging) has a good material contrast and a high-resolution and has therefore been proposed to be used to clean spectroscopic images, in this case by non-local filtering.

BSE images may be used as prior information on edge location because it is higher resolved than the typical EDX spectral channels. This may be modeled in the reconstruction framework as an additional prior.

Such prior can be used with the optimization scheme of Eq. 5, e.g. in conjunction with the spatial convolution model of Eq. 6. The following then replaces the term “priors”.

$$priors = {\sum }_{i} {\int }_{x} g ( x ) {\vert ∇ {ρ}_{i} \vert}_{x} \vert dx \qquad ( 16 )$$

This formulation is a modification of an edge term in certain known models where it was introduced in a segmentation context. The function g has a low value at edge locations as determined by the guide image I_{g}, e.g. the BSE image. As an example, g(x)=exp(−a|∇I|ₓ|^{b}) with a=10, b=0,55 is used. It has a high value in other image regions. This encourages jumps in the functions ρᵢ to occur in the regions with a low value of g(x), whereas in other regions, constant functions ρᵢ are encouraged. It is useful to have a user-adjustable regularization parameter multiplying the prior term, Eq. 16.

In conclusion, techniques are described resulting in an improvement of volumetric spatial resolution by using-via a spatial deconvolution-knowledge of the interaction volumes of the electron microscope with a material sample, and further resulting in an improvement of a spectral deconvolution, i.e. the identification of material emission lines form measured and recorded EDX spectra. One approach discussed above is interleaved EDX imaging and optimization fitting (compare for example equations (5) and (10) above) to obtain structural 3D information. Further, the knowledge of a material library of possible materials present in the sample is exploited. With this knowledge, for example, stable solutions are achieved.

What is claimed is:

1. A method, comprising:
a) preparing a layer of a semiconductor sample by etching an initial sample surface using a focused ion beam, the semiconductor sample comprising structures of different elemental composition;
b) aligning a surface area of a region of interest volume of the prepared layer of the semiconductor sample with an object field of a scanning electron microscope (SEM);
c) adjusting an electron energy of an electron beam of the SEM;
d) probing the region of interest volume using the scanning electron beam within the object field;
e) detecting X-rays emanating from the aligned region of interest volume;
f) post-processing a detection signal obtained during e) to spatially deconvolute the detection signal into structure data attributed to the sample structure within the region of interest volume;
g) repeating a) through f) until layer by a layer investigation of a superimposed volume of interest of the semiconductor sample is completed.

2. The method of claim 1, wherein e) comprises using wavelength dependent X-ray detection.

3. The method of claim 2, wherein f) comprises a spectral deconvolution of the detected X-rays.

4. The method of claim 1, wherein f) takes into account a volume interaction of the electron beam with the semiconductor sample in the region of interest volume.

5. The method of claim 1, wherein f) takes into account an elemental mapping of elements within the semiconductor sample probed in the region of interest volume.

6. The method of claim 1, wherein f) comprises a Monte-Carlo simulation of the interaction between the probe electrons and the sample material.

7. The method of claim 1, wherein f) comprises geometry input or another a priori condition input from further measurements.

8. The method of claim 1, further comprising:
defining a Point Spread Function that, for each value of n, has a kernel value Kₙ representing a behavior of the probing beam in a bulk of the sample for a given beam parameter value;
defining a spatial variable V that represents a physical property of the sample as a function of position in its bulk;
defining an imaging quantity that, for each value of n, has a value Qₙ that is a multi-dimensional convolution of Kₙ and V, such that Qₙ=Kₙ*V; and
for each value of n, computationally determining a minimum divergence
$$min D ( {M}_{n} ‖ {K}_{n} * V )$$
between Mₙ and Qₙ, which is solved for V while applying constraints on the values Kₙ.

9. The method of claim 8, wherein the constraints on the values Kₙ are derived using at least one method selected from the group consisting of: computational simulation of at least a set of values Kₙ; empirically determining at least a set of values Kₙ; modelling the Point Spread Function as a parametrized function with a limited number of modeling parameters, on the basis of which at least a set of values Kₙ can be estimated; logical solution space limitation, whereby theoretically possible values Kₙ that are judged to be physically meaningless are discarded; and interference of a second set of values Kₙ by applying extrapolation and/or interpolation to a first set of values Kₙ.

10. The method of claim 9, wherein e) comprises using wavelength dependent X-ray detection.

11. The method of claim 10, wherein f) comprises a spectral deconvolution of the detected X-rays.

12. The method of claim 1, wherein:
e) comprises using wavelength dependent X-ray detection;
f) comprises a spectral deconvolution of the detected X-rays; and
at least one of the following holds:
f) takes into account a volume interaction of the electron beam with the semiconductor sample in the region of interest volume;
f) takes into account an elemental mapping of elements within the semiconductor sample probed in the region of interest volume;
f) comprises a Monte-Carlo simulation of the interaction between the probe electrons and the sample material; and
f) comprises geometry input or another a priori condition input from further measurements.

13. The method of claim 1, wherein:
e) comprises using wavelength dependent X-ray detection; and
at least one of the following holds:
f) takes into account a volume interaction of the electron beam with the semiconductor sample in the region of interest volume;
f) takes into account an elemental mapping of elements within the semiconductor sample probed in the region of interest volume;
f) comprises a Monte-Carlo simulation of the interaction between the probe electrons and the sample material; and
f) comprises geometry input or another a priori condition input from further measurements.

14. One or more machine-readable hardware storage devices comprising instructions that are executable by one or more processing devices to perform operations comprising the method of claim 1.

15. A system, comprising:
one or more processing devices; and
one or more machine-readable hardware storage devices comprising instructions that are executable by one or more processing devices to perform operations comprising the method of claim 1.

16. The system of claim 15, further comprising:
a FIB source;
an SEM; and
an X-ray detection device.

17. The system of claim 16, wherein the X-ray detection device comprises an X-ray spectrometer.

18. The system of claim 16, wherein the system is configured so that the SEM probes the sample at angle of less than 90° measured from an initial bulk sample surface plane.

19. The system of claim 16, wherein the system is configured so that X-ray detection device detects the X-rays at an angle of less than 90° measured from an initial bulk sample surface plane.

20. The system of claim 16, wherein the system is configured so that FIB source etches the sample in an etching plane which has an angle between 20° and 60° with an initial bulk sample surface plane.
